(19) United States
(12) Patent Application Publication
(10) Pub. No.: US 2025/0391712 A1
(43) Pub. Date: Dec. 25, 2025

(54) MANUFACTURING TESTSITE STRUCTURES FOR QUANTUM PROCESSORS AND CIRCUITS

(71) Applicant: International Business Machines Corporation, Armonk, NY (US)

(72) Inventors: Jeffrey W. Sleight, Ridgefield, CT (US); Isaac Lauer, Chappaqua, NY (US); Karthik Balakrishnan, Scarsdale, NY (US); David James Frank, Yorktown Heights, NY (US)

(21) Appl. No.: 18/754,039

(22) Filed: Jun. 25, 2024

(51) Int. Cl. H01L 21/66; G01R 1/073; G01R 27/08; G01R 31/28; G01R 31/54; H10N 60/01; H10N 60/80

(52) U.S. Cl. CPC H01L 22/34; G01R 1/07342; G01R 27/08; G01R 31/2884; G01R 31/54; H10N 60/0912; H10N 60/805

(57) ABSTRACT

An insulator region is fabricated in a semiconductor substrate of a wafer and a metal layer is fabricated on the semiconductor substrate. Test circuitry is fabricated on a first portion of the metal layer, the first portion residing at least partially over the insulator region. Quantum circuitry is fabricated on a second portion of the metal layer.

### BACKGROUND

The present invention relates generally to the electrical, electronic and computer arts and, more particularly, to quantum computers, quantum circuits and computer-aided hardware design.

In superconducting quantum processor chips, a metal layer is conventionally applied on the underlying substrate. While the quantum processor chip is typically operated at cryogenic temperatures, testing of the quantum processor chip is typically conducted at, for example, room temperature. At room temperature, the substrate has a finite conductance, which complicates measurements of various test structures on the quantum processor chip.

### BRIEF SUMMARY

Principles of the invention provide systems and techniques for manufacturing testsite structures for quantum processors and circuits. In one aspect, an exemplary method includes the operations of fabricating an insulator region in a semiconductor substrate of a wafer; fabricating a metal layer on the semiconductor substrate; fabricating test circuitry on a first portion of the metal layer, the first portion residing at least partially over the insulator region; and fabricating quantum circuitry on a second portion of the metal layer.

In one aspect, a circuit device comprises a semiconductor substrate; an insulator region embedded in the semiconductor substrate; a metal layer on the semiconductor substrate; and test circuitry on a first portion of the metal layer, the first portion residing at least partially over the insulator region.

In one aspect, a system comprises a circuit device comprising a semiconductor substrate, an insulator region embedded in the semiconductor substrate, a metal layer on the semiconductor substrate, and test circuitry on a first portion of the metal layer, the first portion residing at least partially over the insulator region, the test circuitry comprising test structures and test pads; a prober comprising a probe card configured to land at least one probe on at least one of the test pads and a source-measurement circuit configured to measure current-voltage characteristics of each of the test structures; and a controller configured to control the source-measurement circuit to measure the current-voltage characteristics of each of the test structures.

As used herein, “facilitating” an action includes performing the action, making the action easier, helping to carry the action out, or causing the action to be performed. Thus, by way of example and not limitation, instructions executing on a processor might facilitate an action carried out by semiconductor and quantum circuit fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
monitoring of manufacturing electrical structures, which is key to understanding yield impacts, process variation control and the like; and
improved monitoring of manufacturing test structures by eliminating the substrate shunting resistance that impairs measurements and testing.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates a top view of a semiconductor chip and a side view of a semiconductor substrate for the semiconductor chip, in accordance with example embodiments;

FIG. 2 illustrates a top view and a side view of an example wafer, in accordance with example embodiments;

FIG. 3 is a high-level diagram of a system for testing the circuit device, in accordance with example embodiments;

FIG. 4 depicts a computing environment according to an embodiment of the present invention; and

FIG. 5 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As used herein, a “tunnel junction” is a structure including a metal, an insulator, and a metal where, for a qubit structure, the metals superconduct at cryogenic temperatures. As used herein, “kerf” refers to a manufacturing electrical test region, and is often in a sacrificial area in the scribe lane (the area between devices on a wafer) of the chip.

### Quantum Processor Electrical Test Structures

High volume room temperature electrical testing is a key component to understand and improve yields as processor size and device count/complexity increases. Conventionally, the electrical test structures for wafer-level tests, screening, and the like can monitor many device elements, such as tunnel junction resistance, through-substrate via (TSV) via chains, room temperature (RT) metal resistances, and the like. In example embodiments, TSVs are monitored through current-voltage measurements to determine if the resistance conforms to design specifications. In addition, electrical current continuity is measured to determine yield (open defects). In the qubit device structures under test, a metal layer typically resides in direct contact with a semiconductor substrate that is conductive at room temperature. (Classical very large scale integration (VLSI) logic does not typically have a metal layer in direct contact with the semiconductor substrate.) In quantum processors, however, it is common to have a metal layer in direct contact with the semiconductor substrate. This metal layer is superconducting at cold temperatures (for example, at less than 5 Kelvin). However, the substrate is conductive at room temperature. Because of this, the semiconductor substrate has a parasitic shunting resistance that typically presents itself in many measurements. This parasitic shunting resistance can vary significantly depending on many parameters (for example, substrate doping concentration, metal pattern density, substrate-metal interface bandgap structure, substrate defectivity and the like), complicating the obtaining of absolute measurements.

### Exemplary Structure and Method

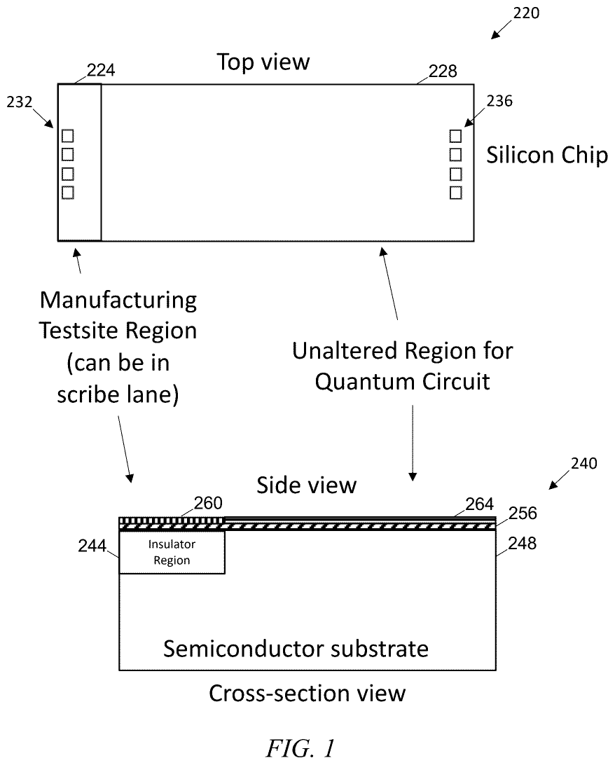

FIG. 1 illustrates a top view of a semiconductor chip 220 and a side view of a semiconductor substrate 240 for the semiconductor chip 220, in accordance with example embodiments. (Silicon is a non-limiting example of a semiconductor.) The semiconductor chip 220 includes a testsite region 224 (also referred to as test structure region 224 herein) with bond pads 232 and a circuit region 228 with bond pads 236. To electrically isolate the electrical test (kerf) circuits 260 of the testsite region 224, a variety of methods can be used, such as trench etch, dielectric fill (such as SiO₂, SiN), chemical mechanical polishing (CMP) and selective silicon on insulator (SOI). The resulting chip and/or wafer will then have two regions for at least one of the semiconductor chips 220 on the wafer: an unaltered substrate region 248 on which the quantum circuitry/processor 264 will be fabricated and an insulator region 244 on which the test structures 260 (test circuitry 260) will be fabricated. The testsite region 224 will no longer have a shunting resistance due to the insulator region 244 in the semiconductor substrate 240 under the testsite region 224. Thus, even though a metal layer 256 resides on the semiconductor substrate 240, including under the testsite region 224, measurements in the test circuitry 260 may be performed without influence from a shunting resistance generated by the semiconductor substrate 240. It is noted that the test circuitry 260 may reside entirely over the insulator region 244 or partially over the insulator region 244.

It is noted that the insulator region is typically needed on at least one chip on the wafer. However, it is common practice to have the insulator region on every chip on the wafer, as the chip manufacturing process generally lends itself to having many identical chips on each wafer. In addition, having the insulator region present on multiple chips on the wafer allows for improved characterization of the test structures across the entirety of the wafer.

Example sub-elements of the quantum circuit that can be included in the kerf region are: 1) a 2-point or 4-point Kelvin structure for measuring the resistance of one Josephson tunneling junction, or more than one Josephson tunneling junction in series, parallel, or a combination of both, 2) 2-point or 4-point Kelvin structures, serpentine, or comb structures of metal lines which are representative of superconducting resonators in the quantum circuit, and 3) 2-point or 4-point Kelvin structures, serpentine, or comb structures for TSVs which are representative of signal delivery or ground plane TSVs in the quantum circuit. The metal layer can be a single metal layer fabricated from one material, or a stack of one or more metal sub-layers fabricated from one or more different materials in some order from bottom to top. The metal stack can include only superconducting materials, or a combination of superconducting materials and non-superconducting materials; for example, a single metal layer of Niobium (Nb), or a stack of Tantalum (Ta) or Tantalum nitride (TaN) metal. In example embodiments, the typical thickness of the single metal layer or the total thickness of the stack of metal layers is 20-100 nanometer (nm) (or more generally 10 nm-500 nm). Furthermore, the metal layer on the semiconductor substrate could also be the bottom-most metal sub-layer in a stack of metallization layers separated by interlayer dielectrics, which are connected through vias.

In example embodiments, the test region 224 is kept or discarded after testing based on a given specification. For example, the test region 224 may be kept or discarded after the testing of the wafer on a per-chip basis. In example embodiments, the test region 224 is discarded after testing as part of the dicing process.

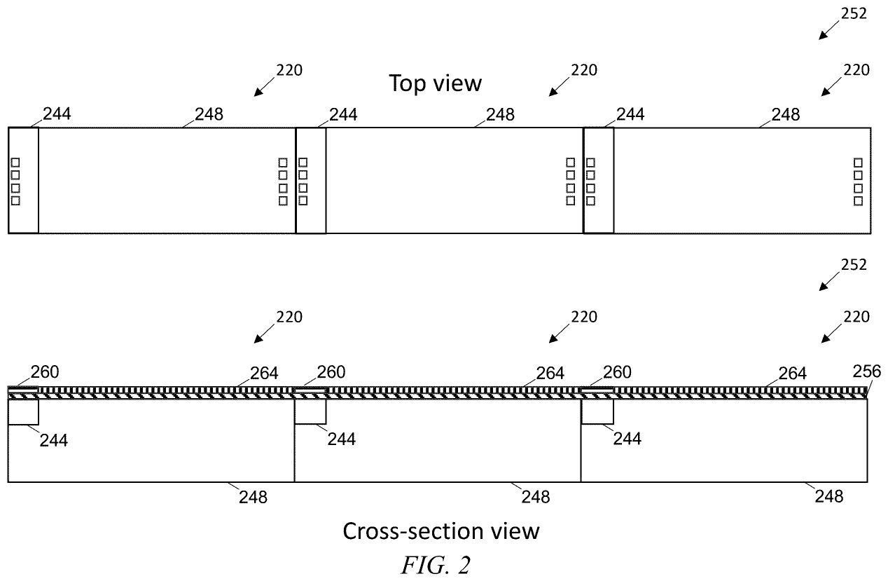

FIG. 2 illustrates a top view and a side view of an example wafer 252, in accordance with example embodiments. In one example embodiment, the wafer 252 includes a plurality of semiconductor chips 220. The testing process involves either dicing chips from the wafer or keeping the wafer intact, followed by measurement of the test region using a prober. The prober includes a probe card used to land probes on the test structure area and a source-measure unit to measure the current-voltage characteristics of each of the test structures. In example embodiments, it also includes a test plan (e.g., program statements or instructions in a memory; a computer file with parameters or instructions for the test; and the like) which specifies, for example, the input currents and/or voltages to apply for each device under test (DUT). In example embodiments, the prober can optionally perform measurements at elevated temperatures (for example, 100 degrees Celsius) or reduced temperatures (for example, 50 degrees Celsius).

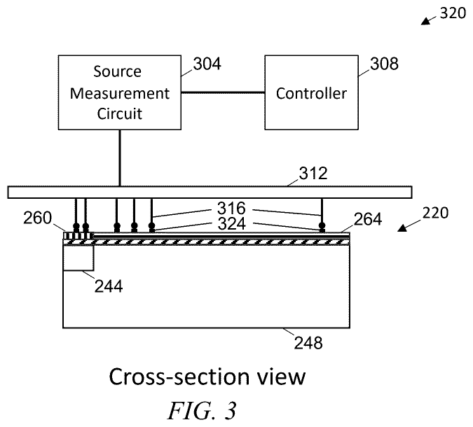

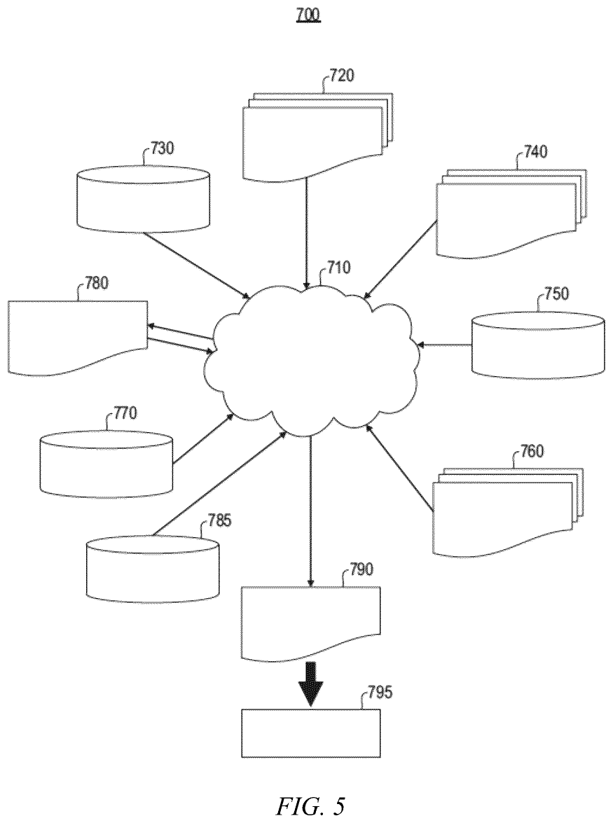

FIG. 3 is a high-level diagram of a system for testing the circuit device 220, in accordance with example embodiments. A prober 320 includes a probe card 312 configured to land probes 316 on corresponding test pads 324 of the test circuitry 260 and the quantum circuitry 264. A source-measurement circuit 304 is configured to measure current-voltage characteristics of, for example, each of the test structures of the test circuitry 260. A controller 308 is configured to control the source-measurement circuit 304 when measuring the current-voltage characteristics of each of the test structures. Circuit 304 can be implemented with a commercial digital ammeter and voltmeter or custom digital circuitry designed and fabricated as per FIG. 5.

Given the discussion thus far, it will be appreciated that, in general terms, an exemplary method, according to an aspect of the invention, includes the operations of fabricating an insulator region 244 in a semiconductor substrate 240 of a wafer; fabricating a metal layer 256 on the semiconductor substrate 240; fabricating test circuitry 260 on a first portion of the metal layer 256, the first portion residing at least partially over the insulator region 244; and fabricating quantum circuitry 264 on a second portion of the metal layer.

In one example embodiment, the test circuitry 260 is utilized to obtain measurements associated with the quantum circuitry 264.

In one example embodiment, the utilizing of the test circuitry 260 is performed at room temperature.

In one example embodiment, the wafer is diced to create a plurality of semiconductor chips 220.

In one example embodiment, at least one of the plurality of diced semiconductor chips 220 does not include any portion of the test circuitry 260.

In one example embodiment, at least one of the plurality of diced semiconductor chips 220 includes at least a portion of the test circuitry 260.

In one example embodiment, the fabricating the insulator region 244 further comprises electrically isolating the test circuitry 260 of the testsite region 224 using at least one of trench etch, dielectric fill, chemical mechanical polishing (CMP) and selective semiconductor on insulator (SOI).

In one aspect, a circuit device comprises a semiconductor substrate 240; an insulator region 244 embedded in the semiconductor substrate 240; a metal layer 256 on the semiconductor substrate 240; and test circuitry 260 on a first portion of the metal layer 256, the first portion residing at least partially over the insulator region 244.

In one example embodiment, the circuit device further comprises quantum circuitry 264 on a second portion of the metal layer 256.

In one example embodiment, the test circuitry 260 comprises one or more of a Kelvin structure for measuring a resistance of one or more Josephson tunneling junctions, one or more Kelvin structures, serpentine, and comb structures of metal lines which are representative of superconducting resonators in a quantum circuit and one or more of Kelvin structures, serpentine, and comb structures for TSVs which are representative of signal delivery TSVs, ground plane TSVs or both in the quantum circuit. The skilled artisan is familiar with Josephson tunneling junctions, Kelvin structures for measuring a resistance, serpentine and comb structures of metal lines, superconducting resonators in a quantum circuit, TSVs, signal delivery TSVs, and ground plane TSVs and thus they are shown at a high-level.

In one example embodiment, the metal layer is fabricated as a stack of one or more metal sub-layers fabricated from one or more different materials.

In one example embodiment, a stack of metallization layers is separated by interlayer dielectrics, the stack residing on top of the metal layer.

In one example embodiment, the stack comprises a combination of at least one superconducting material and at least one non-superconducting material.

In one example embodiment, a thickness of the metal layer or a thickness of the stack of metallization layers is 20-100 nanometers.

In one example embodiment, the test circuitry 260 comprises electrical test structures configured to monitor device elements.

In one example embodiment, the device elements comprise one or more of tunnel junction resistances and room temperature (RT) metal resistances.

In one example embodiment, the electrical test structures are configured to monitor TSVs through current-voltage measurements to determine if a resistance conforms to given design specifications.

In one example embodiment, the electrical test structures are configured to measure electrical current continuity to identify open defects of the circuit device.

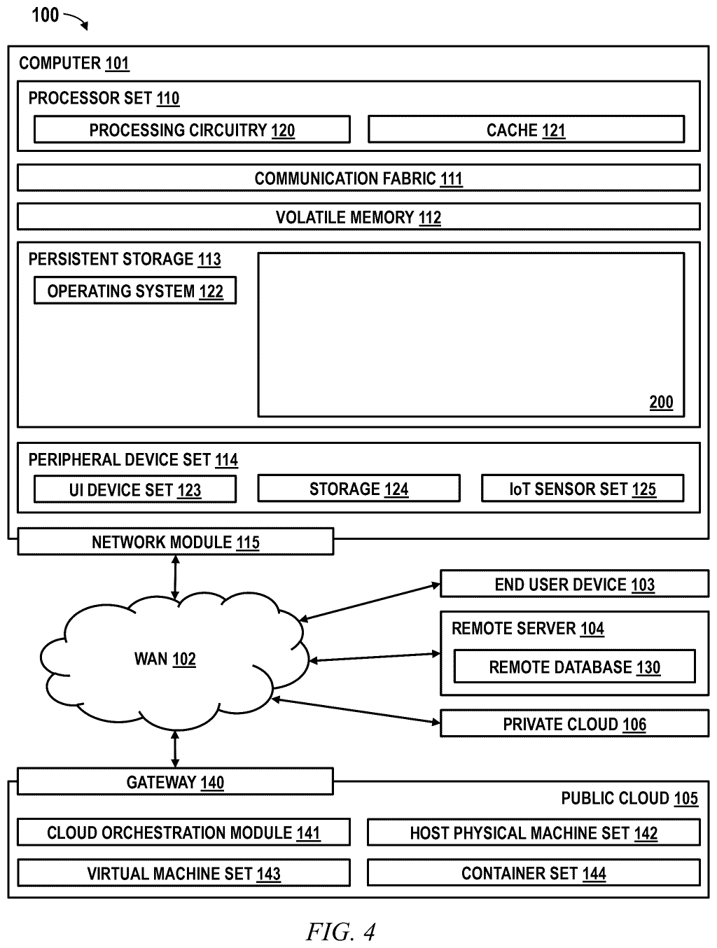

In one aspect, and referring also to FIG. 3, a system comprises a circuit device comprising a semiconductor substrate 240, an insulator 244 region embedded in the semiconductor substrate 240, a metal layer 256 on the semiconductor substrate 240, and test circuitry 260 on a first portion of the metal layer 256, the first portion residing at least partially over the insulator region 244, the test circuitry 260 comprising test structures and test pads 324; a prober 320 comprising a probe card 312 configured to land at least one probe 316 on at least one of the test pads 324, a source-measurement circuit 304 configured to measure current-voltage characteristics of each of the test structures and a controller 308 configured to control the source-measurement circuit 304 to measure the current-voltage characteristics of each of the test structures. The skilled artisan will have general familiarity with test fixturing per se and given the teachings herein, can adapt known systems to test inventive devices under test and to implement inventive instructions in the controller 308. Controller 308 can be a digital circuit controller or control could be done in software or there can be a mixture of both. The general computer in FIG. 4 can implement software control using block 200, for example, and can also control a design and fabrication process of FIG. 5 to implement a digital hardware controller.

In one example embodiment, the system comprises a test plan in memory (see discussion of memory with respect to FIG. 4) which specifies input currents, voltages or both to apply for each device under test (DUT).

The controller 308 can be further configured to cause the system to implement any one, some, or all of the method steps disclosed herein.

The skilled artisan will be generally familiar with conventional training of and inferencing with RPU arrays and, given the teachings herein, will be able to implement novel CMOS-based resistive processing units/arrays with asymmetric update.

Refer now to FIG. 4.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as controller code 200 for testing quantum processors and/or circuits having test sites, in accordance with aspects of the invention. In one or more embodiments, controller 200 controls the test cycle. Code 200 also represents code implementing software aspects of the process in FIG. 5. In any case, code 200 can interface with other components over WAN 102 and the other components correspond to the end user device 103, but this is an example and there could be direct connection, cabling, a wireless LAN, etc. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 5 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 5 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as Cor C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
fabricating an insulator region in a semiconductor substrate of a wafer;
fabricating a metal layer on the semiconductor substrate;
fabricating test circuitry on a first portion of the metal layer, the first portion residing at least partially over the insulator region; and
fabricating quantum circuitry on a second portion of the metal layer.

2. The method of claim 1, further comprising utilizing the test circuitry to obtain measurements associated with the quantum circuitry.

3. The method of claim 2, wherein the utilizing of the test circuitry is performed at room temperature.

4. The method of claim 2, further comprising dicing the wafer to create a plurality of semiconductor chips.

5. The method of claim 4, wherein at least one of the plurality of diced semiconductor chips does not include any portion of the test circuitry.

6. The method of claim 4, wherein at least one of the plurality of diced semiconductor chips includes at least a portion of the test circuitry.

7. The method of claim 1, wherein the fabricating of the insulator region further comprises electrically isolating the test circuitry of the testsite region using at least one of trench etch, dielectric fill, chemical mechanical polishing (CMP), and selective silicon on insulator (SOI).

8. A circuit device comprising:
a semiconductor substrate;
an insulator region embedded in the semiconductor substrate;
a metal layer on the semiconductor substrate; and
test circuitry on a first portion of the metal layer, the first portion residing at least partially over the insulator region.

9. The circuit device of claim 8, further comprising quantum circuitry on a second portion of the metal layer.

10. The circuit device of claim 8, wherein the test circuitry comprises one or more of:
a Kelvin structure for measuring a resistance of one or more Josephson tunneling junctions, one or more Kelvin structures, serpentine, and comb structures of metal lines which are representative of superconducting resonators in a quantum circuit; and
one or more of Kelvin structures, serpentine, and comb structures for through-substrate vias which are representative of signal delivery through-substrate vias, ground plane through-substrate vias or both in the quantum circuit.

11. The circuit device of claim 8, wherein the metal layer includes a stack of one or more metal sub-layers of one or more different materials.

12. The circuit device of claim 8, further comprising a stack of metallization layers separated by interlayer dielectrics, the stack residing on top of the metal layer.

13. The circuit device of claim 12, wherein the stack comprises a combination of at least one superconducting material and at least one non-superconducting material.

14. The circuit device of claim 12, wherein a thickness of the stack of metallization layers is 20-100 nanometers.

15. The circuit device of claim 8, wherein a thickness of the metal layer is 20-100 nanometers.

16. The circuit device of claim 8, wherein the test circuitry comprises electrical test structures configured to monitor device elements.

17. The circuit device of claim 16, wherein the device elements comprise one or more of tunnel junction resistances and room temperature (RT) metal resistances.

18. The circuit device of claim 16, wherein the electrical test structures are configured to monitor through-substrate vias through current-voltage measurements to determine if a resistance conforms to given design specifications.

19. The circuit device of claim 16, wherein the electrical test structures are configured to measure electrical current continuity to identify open defects of the circuit device.

20. A system comprising:
a circuit device comprising:
a semiconductor substrate;
an insulator region embedded in the semiconductor substrate;
a metal layer on the semiconductor substrate; and
test circuitry on a first portion of the metal layer, the first portion residing at least partially over the insulator region, the test circuitry comprising test structures and test pads;
a prober comprising:
a probe card configured to land at least one probe on at least one of the test pads; and
a source-measurement circuit configured to measure current-voltage characteristics of each of the test structures; and
a controller configured to control the source-measurement circuit to measure the current-voltage characteristics of each of the test structures.
